(19) United States
(12) Patent Application Publication
(10) Pub. No.: US 2025/0155534 A1
(43) Pub. Date: May 15, 2025

(54) METHODS, SYSTEMS, DEVICES, AND STORAGE MEDIA FOR MAGNETIC RESONANCE IMAGING

(71) Applicant: SHANGHAI UNITED IMAGING HEALTHCARE CO., LTD., Shanghai (CN)

(72) Inventor: Yongquan YE, Houston, TX (US)

(73) Assignee: SHANGHAI UNITED IMAGING HEALTHCARE CO., LTD., Shanghai (CN)

(21) Appl. No.: 18/898,668

(22) Filed: Sep. 26, 2024

(30) Foreign Application Priority Data
Nov. 9, 2023 (CN) 202311491225.7

(51) Int. Cl. G01R 33/48; G01R 33/561

(52) U.S. Cl. CPC G01R 33/482; G01R 33/561

(57) ABSTRACT

A method for MRI is provided. The method comprises obtaining k-space data collected during an MR scan of a target object, which is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules. For each signal acquisition module, the method further comprises determining a target k-space data set and reconstructing an MR image of the target object corresponding to the signal acquisition module based on the target k-space data set.

### CROSS-REFERENCE TO RELATED APPLICATIONS

This application claims priority to Chinese Patent Application No. 202311491225.7, filed on Nov. 9, 2023, the content of which is hereby incorporated by reference.

### TECHNICAL FIELD

The present disclosure relates to the field of medical imaging technology, and in particular, to methods, systems, devices, and storage media for magnetic resonance imaging.

### BACKGROUND

Magnetic resonance (MR) imaging is a technique that utilizes a magnetic resonance phenomenon for imaging. MR imaging is increasingly used in health examinations and disease screening. However, an MR scan is generally designed to obtain image signals with a relatively fixed image contrast through a relatively fixed magnetic resonance imaging sequence. When collecting image signals with different image contrasts, complex calculations need to be carried out on the obtained image signals with relatively fixed image contrasts or the design of the imaging sequence needs to be changed to perform multiple MR scans. This solution is relatively cumbersome, has relatively high design costs, and is prone to errors, which is not conducive to practical application.

Therefore, it is desirable to provide methods, systems, devices, and storage media for MR imaging.

### SUMMARY

An aspect of the present disclosure relates to a method for MRI, implemented on a computing device having at least one processor and at least one storage device. The method comprises: obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules; and for each signal acquisition module of the at least two signal acquisition modules, determining a target k-space data set based on the k-space data set corresponding to the signal acquisition module and the one or more k-space data sets corresponding to one or more other signal acquisition modules among the at least two signal acquisition modules; and reconstructing an MR image of the target object corresponding to the signal acquisition module based on the target k-space data set.

In some embodiments, the at least two design characteristics include a first design characteristic, and the first design characteristic relates to the type and the count of elements included in each signal acquisition module.

In some embodiments, the elements include at least one of a pulse, a flip angle, a readout gradient polarity, an echo signal acquisition, or a magnetization preparation strategy.

In some embodiments, the at least two design characteristics further include a second design characteristic, and the second design characteristic relates to a scanning parameter corresponding to each signal acquisition module.

In some embodiments, the determining a target k-space data set includes: determining a k-space outer region corresponding to the signal acquisition module and outer k-space data in the k-space outer region collected by the signal acquisition module based on the k-space data set corresponding to the signal acquisition module; determining reference k-space data, wherein the reference k-space data includes k-space data in the k-space outer region collected by the one or more other signal acquisition modules; updating the outer k-space data based on the reference k-space data; and determining the target k-space data set based on the updated outer k-space data and original k-space data in other regions in k-space collected by the signal acquisition module.

In some embodiments, the k-space outer region corresponding to the signal acquisition module is determined based on the size of k-space and the quality of k-space data in the k-space data set corresponding to the signal acquisition module.

In some embodiments, the one or more other signal acquisition modules include multiple other signal acquisition modules, and the updating the outer k-space data based on the reference k-space data includes: for each of the other signal acquisition modules, determining a weight of the other signal acquisition module based on first characteristic values of the at least two design characteristics of the signal acquisition module and second characteristic values of the at least two design characteristics of the other signal acquisition module; and updating the outer k-space data based on the reference k-space data and the weight of each of the other signal acquisition modules.

In some embodiments, the updating the outer k-space data based on the reference k-space data includes: for each of the one or more other signal acquisition modules, determining reference outer k-space data based on k-space data in the k-space outer region collected by the other signal acquisition module, first characteristic values of the at least two design characteristics of the signal acquisition module, and second characteristic values of the at least two design characteristics of the other signal acquisition module; and updating the outer k-space data based on the reference outer k-space data corresponding to the one or more other signal acquisition modules.

In some embodiments, the method further comprises: generating a quantitative parameter map based on the MR images corresponding to the at least two signal acquisition modules.

In some embodiments, the one or more other signal acquisition modules include multiple other signal acquisition modules, the determining a target k-space data set includes: determining, based on first characteristic values of the at least two design characteristics of the signal acquisition module and second characteristic values of the at least two design characteristics of each of the other signal acquisition modules, one or more target signal acquisition modules from the other signal acquisition modules; and determining the target k-space data set based on the k-space data sets of the one or more target signal acquisition modules.

In some embodiments, the determining one or more target signal acquisition modules from the other signal acquisition modules includes: for each of the other signal acquisition modules, determining a difference between the signal acquisition module and the other signal acquisition module based on the first characteristic values of the signal acquisition module and the second characteristic values of the other signal acquisition module; obtaining a difference threshold; and in response to determining that the difference is less than the difference threshold, designating the other signal acquisition module as one of the one or more target signal acquisition modules.

In some embodiments, the at least two signal acquisition modules are configured to under-sample different locations in k-space utilizing a same undersampling pattern.

A second aspect of the present disclosure relates to a system for MRI. The system comprises at least one storage device storing a set of instructions for MRI; and at least one processor configured to communicate with the at least one storage device. When executing the set of instructions, the at least one processor is configured to direct the system to perform operations including: obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules; and for each signal acquisition module of the at least two signal acquisition modules, determining a target k-space data set based on the k-space data set corresponding to the signal acquisition module and the one or more k-space data sets corresponding to one or more other signal acquisition modules among the at least two signal acquisition modules; and reconstructing an MR image of the target object corresponding to the signal acquisition module based on the target k-space data set.

A third aspect of the present disclosure relates to a non-transitory computer readable medium, comprising a set of instructions, wherein when executed by at least one processor, the set of instructions direct the at least one processor to effectuate a method a method for MRI.

Additional features will be set forth in part in the description which follows, and in part will become apparent to those skilled in the art upon examination of the following and the accompanying drawings or may be learned by production or operation of the examples. The features of the present disclosure may be realized and attained by practice or use of various aspects of the methodologies, instrumentalities, and combinations set forth in the detailed examples discussed below.

### BRIEF DESCRIPTION OF THE DRAWINGS

The present disclosure is further illustrated in terms of exemplary embodiments. These exemplary embodiments are described in detail with reference to according to the drawings. These embodiments are non-limiting exemplary embodiments, in which like reference numerals represent similar structures, and wherein:

FIG. 1 is a schematic diagram illustrating an exemplary MR imaging system according to some embodiments of the present disclosure;

FIG. 2 is a schematic diagram illustrating exemplary modules of an MR imaging system according to some embodiments of the present disclosure;

FIG. 3 is a flowchart illustrating an exemplary process for MR imaging according to some embodiments of the present disclosure;

FIG. 4 is a flowchart illustrating an exemplary process for determining a target k-space data set corresponding to a signal acquisition module according to some embodiments of the present disclosure;

FIG. 5 is a schematic diagram illustrating an exemplary k-space outer region according to some embodiments of the present disclosure;

FIG. 6 is a schematic diagram illustrating an exemplary process for updating outer k-space data according to some embodiments of the present disclosure;

FIG. 7 is another schematic diagram illustrating an exemplary process for updating outer k-space data according to some embodiments of the present disclosure;

FIG. 8 is a schematic diagram illustrating an exemplary signal acquisition module including at least two different design characteristics according to some embodiments of the present disclosure;

FIG. 9 is a schematic diagram illustrating an exemplary magnetic resonance image of a target object according to some embodiments of the present disclosure;

FIG. 10 is a schematic diagram illustrating an exemplary process for updating outer k-space data according to some embodiments of the present disclosure; and

FIG. 11 is a schematic diagram illustrating an exemplary process for determining a target k-space data set corresponding to a signal acquisition module according to some embodiments of the present disclosure.

### DETAILED DESCRIPTION

In the following detailed description, numerous specific details are set forth by way of examples in order to provide a thorough understanding of the relevant disclosure. However, it should be apparent to those skilled in the art that the present disclosure may be practiced without such details. In other instances, well-known methods, procedures, systems, components, and/or circuitry have been described at a relatively high level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but to be accorded the widest scope consistent with the claims.

In the following detailed description, numerous specific details are set forth by way of examples in order to provide a thorough understanding of the relevant disclosure. However, it should be apparent to those skilled in the art that the present disclosure may be practiced without such details. In other instances, well-known methods, procedures, systems, components, and/or circuitry have been described at a relatively high level, without detail, in order to avoid unnecessarily obscuring aspects of the present disclosure. Various modifications to the disclosed embodiments will be readily apparent to those skilled in the art, and the general principles defined herein may be applied to other embodiments and applications without departing from the spirit and scope of the present disclosure. Thus, the present disclosure is not limited to the embodiments shown, but is to be accorded the widest scope consistent with the claims.

The terminology used herein is for the purpose of describing particular example embodiments only and is not intended to be limiting. As used herein, the singular forms “a,” “an,” and “the” may be intended to include the plural forms as well, unless the context clearly indicates otherwise. It will be further understood that the terms “comprise,” “comprises,” and/or “comprising,” “include,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It will be understood that the terms “system,” “engine,” “unit,” “module,” and/or “block” used herein are one method to distinguish different components, elements, parts, sections or assemblies of different levels in ascending order. However, the terms may be displaced by another expression if they achieve the same purpose.

Generally, the word “module,” “unit,” or “block,” as used herein, refers to logic embodied in hardware or firmware, or to a collection of software instructions. A module, a unit, or a block described herein may be implemented as software and/or hardware and may be stored in any type of non-transitory computer-readable medium or another storage device. In some embodiments, a software module/unit/block may be compiled and linked into an executable program. It will be appreciated that software modules can be callable from other modules/units/blocks or from themselves, and/or may be invoked in response to detected events or interrupts. Software modules/units/blocks configured for execution on computing devices may be provided on a computer-readable medium, such as a compact disc, a digital video disc, a flash drive, a magnetic disc, or any other tangible medium, or as a digital download (and can be originally stored in a compressed or installable format that needs installation, decompression, or decryption prior to execution). Such software code may be stored, partially or fully, on a storage device of the executing computing device, for execution by the computing device. Software instructions may be embedded in firmware, such as an EPROM. It will be further appreciated that hardware modules/units/blocks may be included in connected logic components, such as gates and flip-flops, and/or can be included of programmable units, such as programmable gate arrays or processors. The modules/units/blocks or computing device functionality described herein may be implemented as software modules/units/blocks, but may be represented in hardware or firmware. In general, the modules/units/blocks described herein refer to logical modules/units/blocks that may be combined with other modules/units/blocks or divided into sub-modules/sub-units/sub-blocks despite their physical organization or storage. The description may be applicable to a system, an engine, or a portion thereof.

It will be understood that when a unit, engine, module, or block is referred to as being “on,” “connected to,” or “coupled to,” another unit, engine, module, or block, it may be directly on, connected or coupled to, or communicate with the other unit, engine, module, or block, or an intervening unit, engine, module, or block may be present, unless the context clearly indicates otherwise. As used herein, the term “and/or” includes any and all combinations of one or more of the associated listed items. The terms “pixel” and “voxel” in the present disclosure are used interchangeably to refer to an element of an image.

These and other features, and characteristics of the present disclosure, as well as the methods of operation and functions of the related elements of structure and the combination of parts and economies of manufacture, may become more apparent upon consideration of the following description with reference to the accompanying drawings, all of which form a part of this disclosure. It is to be expressly understood, however, that the drawings are for the purpose of illustration and description only and are not intended to limit the scope of the present disclosure. It is understood that the drawings are not to scale.

In the present disclosure, a representation of a subject (e.g., an object, a patient, or a portion thereof) in an image may be referred to as “subject” for brevity. For instance, a representation of an organ, tissue (e.g., a heart, a liver, a lung), or an ROI in an image may be referred to as the organ, tissue, or ROI, for brevity. Further, an image including a representation of a subject, or a portion thereof, may be referred to as an image of the subject, or a portion thereof, or an image including the subject, or a portion thereof, for brevity. Still further, an operation performed on a representation of a subject, or a portion thereof, in an image may be referred to as an operation performed on the subject, or a portion thereof, for brevity. For instance, a segmentation of a portion of an image including a representation of an ROI from the image may be referred to as a segmentation of the ROI for brevity.

The present disclosure provides systems and methods for MR imaging. The methods include obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules. The methods further include for each signal acquisition module of the at least two signal acquisition modules, determining a target k-space data set based on the k-space data set corresponding to the signal acquisition module and the one or more k-space data sets corresponding to one or more other signal acquisition modules among the at least two signal acquisition modules. The methods also include for each signal acquisition module of the at least two signal acquisition modules, reconstructing an MR image of the target object corresponding to the signal acquisition module based on the target k-space data set.

According to some embodiments of the present disclosure, signal acquisition manners with different functions are modularized, and different signal acquisition modules are applied in one MR scan, thus images with different contrasts can be obtained in a single scan. At the same time, the quality of image reconstruction can be improved by sharing and multiplexing k-space data sets of different signal acquisition modules.

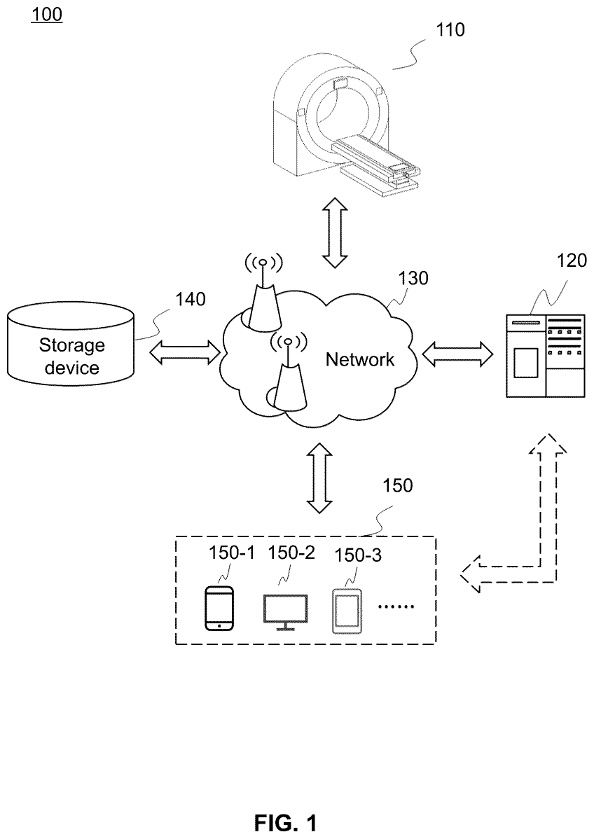

### {{FIG. 1}}

FIG. 1 is a schematic diagram illustrating an exemplary MR imaging system according to some embodiments of the present disclosure. As shown in FIG. 1, an MR imaging system 100 includes an imaging device 110, a processor 120, a network 130, a storage device 140, and a terminal 150.

The imaging device 110 may be configured to scan a target object and generate a scanning image. For example, the imaging device 110 may include an MR scanner. The target object may include a biological object (e.g., a human body, an animal, etc.), a non-biological object (e.g., a phantom), etc. In some embodiments, the target object may include a specific portion, organ, and/or tissue of a patient. For example, the target object may include the head, chest, leg, etc., or any combination thereof, of the patient.

The processor 120 may be configured to process data and/or information obtained from the imaging device 110, the storage device 140, and/or the terminal 150. For example, the processor 120 may obtain k-space data collected during an MR scan of the target object from the imaging device 110. As another example, the processor 120 may determine a target k-space data set corresponding to a signal acquisition module based on a k-space data set of the signal acquisition module and k-space data sets of one or more other signal acquisition modules. As yet another example, the processor 120 may reconstruct an MR image of the target object corresponding to the signal acquisition module based on the target k-space data set.

In some embodiments, the processor 120 may send processing results to the terminal 150. For example, the processor 120 may send an MR image and/or a quantitative parameter map to the terminal 150 for display.

In some embodiments, the processor 120 may be a single server or a group of servers. The server group may be centralized or distributed. In some embodiments, the processor 120 may be local or remote. In some embodiments, the processor 120 may be connected to the imaging device 110, the storage device 140, and/or the terminal 150 via the network 130 or directly to access information and/or data stored thereon. In some embodiments, the processor 120 may be integrated into the imaging device 110. In some embodiments, the processor 120 may be implemented on a cloud platform. Merely by way of example, the cloud platform may include a private cloud, a public cloud, a hybrid cloud, a community cloud, a distributed cloud, an on-premises cloud, a multi-cloud, etc., or any combination thereof.

The network 130 includes any suitable network that may facilitate exchange of information and/or data for the MR imaging system 100. In some embodiments, one or more components of the MR imaging system 100 (e.g., the imaging device 110, the processor 120, the storage device 140, or the terminal 150) may be connected and/or in communication with other components of the MR imaging system 100 via the network 130. For example, the processor 120 may obtain k-space data collected during an MR scan of the target object from the imaging device 110 via the network 130.

In some embodiments, the network 130 may be any one or more of a wired network or a wireless network. For example, the network 130 may include a cable network, a fiber optic network, a telecommunication network, the Internet, a local area network (LAN), a wide area network (WAN), a wireless local area network (WLAN), a metropolitan area network (MAN), a public switched telephone network (PSTN), a Bluetooth network, a ZigBee network, a near-field communication (NFC), an in-device bus, an in-device line, a cable connection, etc. or any combination thereof. Network connections between various portions may be made in one of the ways described above or in more than one way. In some embodiments, the network 130 may be a plurality of topologies such as a peer-to-peer topology, a shared topology, a centralized topology, etc., or a combination of topologies. In some embodiments, the network 130 may include one or more network access points. For example, the network 130 may include wired and/or wireless network access points, such as a base station and/or an Internet access point, through which one or more components of the MR imaging system 100 may be connected to the network 130 to exchange data and/or information.

The storage device 140 may store data, instructions, and/or any other information. In some embodiments, the storage device 140 may store data obtained from the imaging device 110, the processor 120, and/or the terminal 150. In some embodiments, the storage device 140 may store data and/or instructions from the processor 120 for executing exemplary methods described in the present disclosure.

In some embodiments, the storage device 140 may include mass memory, removable memory, volatile read-write memory, read-only memory (ROM), or the like, or any combination thereof. In some embodiments, the storage device 140 may be implemented on the cloud platform.

In some embodiments, the storage device 140 may be connected to the network 130 to communicate with one or more components of the MR imaging system 100 (e.g., the imaging device 110, the processor 120, the terminal 150, etc.). One or more components of the MR imaging system 100 may access data or instructions stored in the storage device 140 via the network 130. In some embodiments, the storage device 140 may be a part of the processor 120.

The terminal 150 may be in communication and/or connection with the imaging device 110, the processor 120, and/or the storage device 140. In some embodiments, the terminal 150 may include one of a mobile device 150-1, a tablet 150-2, a laptop 150-3, etc., or other device with input and/or output capabilities, or any combination thereof. In some embodiments, the terminal 150 may remotely operate the imaging device 110. In some embodiments, the terminal 150 may operate the imaging device 110 via a wireless connection. In some embodiments, the terminal 150 may receive data and/or information from the processor 120. For example, the terminal 150 may receive an MR image and/or a quantitative parameter map from the processor 120. In some embodiments, the terminal 150 may be part of the processor 120. In some embodiments, the terminal 150 may be integrated with the processor 120 as an operator console of the imaging device 110. In some embodiments, the terminal 150 may be omitted.

It should be noted that the descriptions of the MR imaging system 100 are provided for illustrative purposes only and not intended to limit the scope of the present disclosure. For a person of ordinary skill in the art, a variety of modifications or variations may be made according to the description of the present disclosure. For example, the MR imaging system 100 may be implemented on other devices to achieve similar or same functions. The modifications or variations, however, do not depart from the scope of the present disclosure.

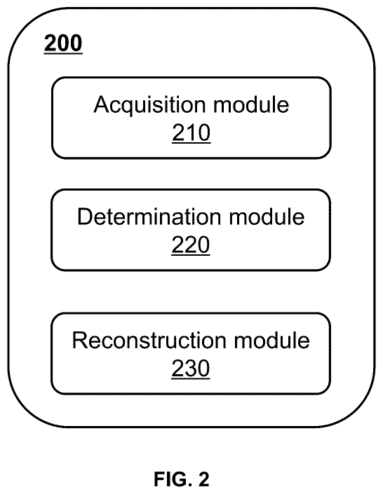

### {{FIG. 2}}

FIG. 2 is a schematic diagram illustrating exemplary modules of an MR imaging system according to some embodiments of the present disclosure. In some embodiments, an MR imaging system 200 includes an acquisition module 210, a determination module 220, and a reconstruction module 230. In some embodiments, the MR imaging system 200 may be implemented by the processor 120 shown in FIG. 1.

The acquisition module 210 is configured to obtain k-space data collected during an MR scan of a target object. The MR scan is performed by applying an imaging sequence to the target object. The imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules. More descriptions regarding obtaining the k-space data may be found in operation 310 and are not repeated here.

The determination module 220 is configured to determine a target k-space data set for a signal acquisition module based on the k-space data set corresponding to the signal acquisition module and the one or more k-space data sets corresponding to one or more other signal acquisition modules among the at least two signal acquisition modules. More descriptions regarding determining the target k-space data set may be found in operation 321 and are not repeated here.

The reconstruction module 230 is configured to reconstruct an MR image of the target object corresponding to a signal acquisition module based on the target k-space data set corresponding to the signal acquisition module. In some embodiments, the reconstruction module 230 is further configured to generate a quantitative parameter map based on the MR images corresponding to the at least two signal acquisition modules. More descriptions regarding generating the MR image and the quantitative parameter map may be found in operation 322 and are not repeated here.

It is to be noted that the above descriptions of the MR imaging system 200 are provided for illustration purposes, and do not limit the present disclosure to the scope of the cited embodiments. It is to be understood that for a person skilled in the art, with an understanding of the principle of the system, it may be possible to arbitrarily combine the modules or form subsystems that are connected to other modules without departing from this principle. In some embodiments, the acquisition module 210, the determination module 220, and the reconstruction module 230 disclosed in FIG. 2 may be different modules in a system, or one module realizing the functions of two or more other modules. For example, the modules may share a common storage module, and the modules may each have a respective storage module. Such deformations are within the scope of protection of the present disclosure.

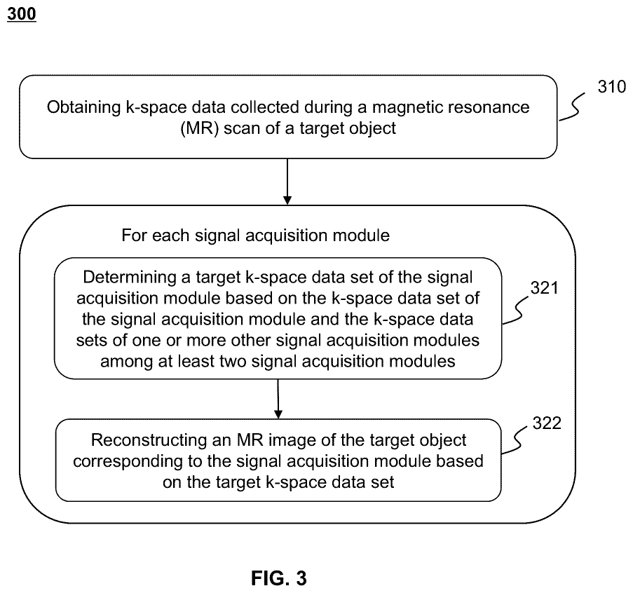

### {{FIG. 3}}

FIG. 3 is a flowchart illustrating an exemplary process for MR imaging according to some embodiments of the present disclosure. In some embodiments, process 300 may be performed by the processor 120 or the MR imaging system 200. For example, the process 300 may be stored in the form of instructions in the storage device 140, and the process 300 may be implemented when the processor 120 or the MR imaging system 200 executes the instructions.

In 310, k-space data collected during an MR scan of a target object is obtained. In some embodiments, operation 310 may be performed by the acquisition module 210.

As used herein, the MR scan refers to a single/one MR scan. The MR scan is performed by applying an imaging sequence to the target object. The imaging sequence includes at least two signal acquisition modules of a same sequence type. A signal acquisition module refers to a smallest imaging unit or MR sequence that is applied to the target object for the purpose of collecting MR data during the MR scan. For example, each signal acquisition module is configured to apply an MR sequence to the target object, and the imaging sequence of the MR scan includes the MR sequences of the at least two signal acquisition modules.

The sequence type of a signal acquisition module refers to the type of MR sequence applied by the signal acquisition module. For example, the sequence type may include a gradient echo (GRE) sequence, a spin echo (SE) sequence, a steady state free precession (SSFP) sequence, and an echo planer imaging (EPI) sequence, etc.

In some embodiments, the at least two signal acquisition modules have the same signal sampling mode. The signal sampling mode refers to the way in which the signal acquisition module samples the MR data of the target object. For example, the signal sampling mode may include radial sampling, helical sampling, Cartesian sampling, etc.

In some embodiments, different signal acquisition modules of the at least two signal acquisition modules have at least two different design characteristics. As used herein, having at least two different design characteristics refers to that different signal acquisition modules have at least two design characteristics with different characteristic values. The design characteristics of a signal acquisition module may relate to elements included in the signal acquisition module, scanning parameters of the signal acquisition module, etc.

In some embodiments, the design characteristics include a first design characteristic. The first design characteristic refers to a feature relating to the type and count of elements included in a signal acquisition module. For example, the first design characteristic may indicate whether the signal acquisition module contains a certain kind of element or a count of the certain kind of element.

An element refers to a basic component of an MR sequence of a signal acquisition module. Exemplary elements include a pulse, a flip angle, a readout gradient polarity, an echo signal acquisition, a magnetization preparation strategy, etc. Merely by way of example, a first design characteristic A may be whether a signal acquisition module includes a magnetization preparation strategy. If a signal acquisition module 1 includes the magnetization preparation strategy and a signal acquisition module 2 does not include the magnetization preparation strategy, the two signal acquisition modules may be considered to have different values of the first design characteristic A. As another example, a first design characteristic B may be a count of flip angles included in a signal acquisition module. If the signal acquisition module 1 contains two flip angles and the signal acquisition module 2 contains three flip angles, the two signal acquisition modules may be considered to have different values of the first design characteristic B. As yet another example, a first design characteristic C may be whether the signal acquisition module includes the flip angle. If the signal acquisition module 1 includes a flip angle of a first degree and the signal acquisition module 2 contains a flip angle of a second degree, the two signal acquisition modules may be considered to have the same value of the first design characteristic C. That is to say, a difference between the degrees of the flip angles does not result in a difference in the characteristic values of the first design characteristic. Designating the type and count of the elements as the first design characteristic, rather than designating values of the elements as the first design characteristic, the differences between different signal acquisition modules may be increased, thereby generating images with more image contrasts.

In some embodiments, the design characteristics include a second design characteristic. The second design characteristic refers to a feature relating to a scanning parameter corresponding to a signal acquisition module.

The scanning parameter refers to a related parameter set for scanning and imaging the target object. In some embodiments, the scanning parameter includes at least one of an imaging resolution, an acquisition acceleration factor, and a k-space undersampling mode. Merely by way of example, the second design characteristic D may relate to an imaging resolution. If the signal acquisition modules 1 and 2 have different imaging resolutions, the two signal acquisition modules may be considered to have different values of the second design characteristic D.

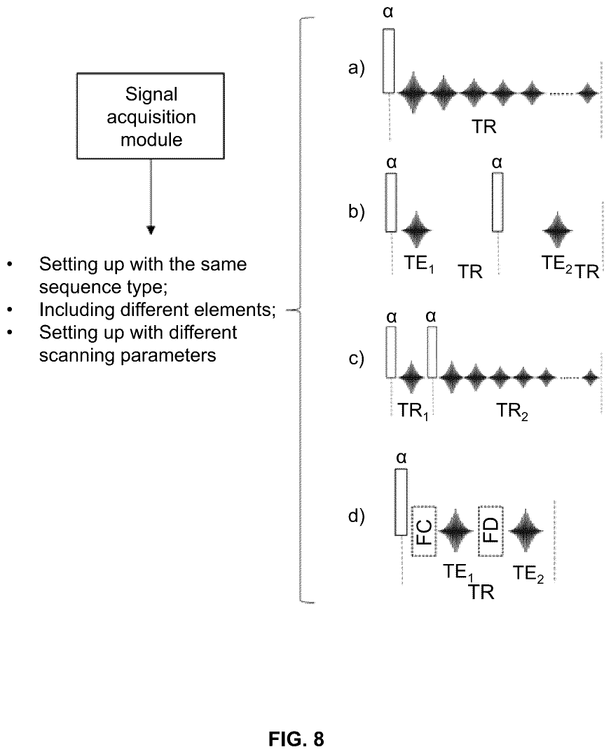

Merely by way of example, as shown in FIG. 8, the signal acquisition modules are set to have the same sequence type, e.g., both of them are gradient echo sequences. Different signal acquisition modules include different elements and/or are set to have different scanning parameters, thus obtaining signal acquisition modules with at least two different design characteristics. For example, the design characteristics include a flip angle, an echo time (TE), a repetition time (TR), and a magnetization preparation strategy. A signal acquisition module a includes one flip angle with a degree of a and one TR, and includes no magnetization preparation strategy. A signal acquisition module b includes two flip angles with the degree of a and two identical TRs, set with different TEs (e.g., TE1 and TE2), and includes no magnetization preparation strategy. A signal acquisition module c includes two flip angles the degree of a and two different TRs (e.g., TR1 and TR2), set up with the same TEs, and includes no magnetization preparation strategy. A signal acquisition module d includes one flip angle with the degree of a, one TR, and magnetization preparation strategies (which include flow compensation (FC) and flow dispersion (FD)), set up with different TEs (e.g., TE1 and TE2). Therefore, the signal acquisition modules a-d having at least two different design characteristics may be obtained.

In some embodiments of the present disclosure, by setting up signal acquisition modules with at least two different design characteristics, more diversified MR data may be obtained, and MR images with more image contrasts may be generated, which provides more data support for clinical analysis.

The k-space data refers to data generated by filling the k-space with MR signals collected by the signal acquisition modules during the MR scan.

In some embodiments, the k-space data includes at least two k-space data sets that correspond to the at least two signal acquisition modules. Each of the at least two k-space data sets corresponds to one of the at least two signal acquisition modules. The k-space data set corresponding to one signal acquisition module may be obtained by filling the k-space with the MR signals collected by the signal acquisition module. In some embodiments, the k-space matrixes corresponding to different signal acquisition modules may have the same size.

In some embodiments, different signal acquisition modules among the at least two signal acquisition modules have different sampling patterns. In some embodiments, for different signal acquisition modules among the at least two signal acquisition modules, a same undersampling pattern may be utilized to under-sample different positions in the k-space. The undersampling pattern of a signal acquisition module relates to a form of sampling lines in the k-space collected by the signal acquisition module and an undersampling rate of the signal acquisition module. If the forms of sampling lines and the undersampling rates collected by two signal acquisition modules are the same, it may be considered that the two signal acquisition modules have the same undersampling pattern. The form of the sampling lines may include Cartesian lines, radial lines, spiral lines, etc. Sampling positions of different signal acquisition modules in the k-space may be completely or partially different.

For example, a Cartesian sampling pattern is utilized by both a signal acquisition module e and a signal acquisition module f. K-space lines corresponding to the signal acquisition module f may be obtained by translating k-space lines corresponding to the signal acquisition module e. Merely by way of example, the signal acquisition module e samples odd Cartesian lines in the k-space utilizing the Cartesian sampling pattern, while the signal acquisition module f samples even Cartesian lines in the k-space utilizing the Cartesian sampling pattern. As another example, both the signal acquisition module e and the signal acquisition module f utilize radial or spiral sampling patterns. Radial or spiral lines corresponding to the signal acquisition module f may be obtained by rotating radial or spiral lines corresponding to the signal acquisition module e.

In some embodiments, k-space data collected by different signal acquisition modules are complementary. For example, different signal acquisition modules sample different positions in the k-space, and these positions may cover the whole k-space outer region. Thus, it is possible to under-sample all positions in the whole k-space outer region by different signal acquisition modules, thereby improving the integrity of the k-space data acquired by different signal acquisition modules.

In some embodiments, since some signal acquisition modules use the same undersampling pattern, the k-space data of one signal acquisition module can have a greater reference value for the other signal acquisition modules. In addition, these signal acquisition modules can under-sample more positions in the k-space to improve the integrity of the k-space data acquired by all signal acquisition modules.

For each signal acquisition module, the processor may implement operation 321 and operation 322, respectively. For illustration purposes, the implementation of operations 321 and 322 for one signal acquisition module is described as an example.

In 321, a target k-space data set is determined based on the k-space data set corresponding to the signal acquisition module and the one or more k-space data sets corresponding to one or more other signal acquisition modules among the at least two signal acquisition modules. In some embodiments, operation 321 may be performed by the determination module 220.

The target k-space data set refers to a data set generated by updating the k-space data set of the signal acquisition module based on k-space data sets of one or more other signal acquisition modules.

In some embodiments, the target k-space data set includes data corresponding to different sampling positions in the k-space. If the k-space data sets of both the signal acquisition module and other signal acquisition modules include data corresponding to the same sampling position in the k-space, the processor may determine an average of the data and designate the average as data corresponding to that sampling position in the target k-space data set. If the k-space data sets of other signal acquisition modules include data corresponding to a sampling position in the k-space, but the k-space data set corresponding to the signal acquisition module does not include data corresponding to that sampling position, the processor may fill the data of the other signal acquisition modules at that sampling position into the target k-space data set (i.e., as data corresponding to that sampling position in the target k-space data set).

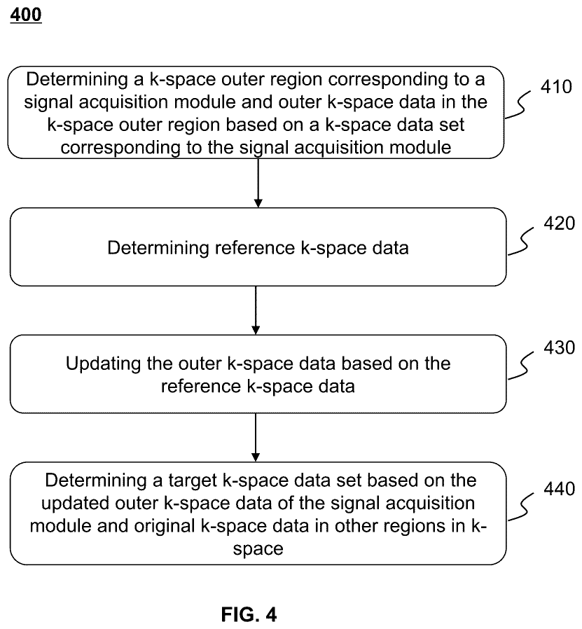

In some embodiments, the processor may determine a k-space outer region corresponding to the signal acquisition module and outer k-space data collected by the signal acquisition module in the k-space outer region; update the outer k-space data based on reference k-space data; determine the target k-space data set based on the updated outer k-space data and the original k-space data in other regions in k-space collected by the signal acquisition module. More descriptions regarding the foregoing embodiments may be found in FIG. 4 and the related descriptions thereof.

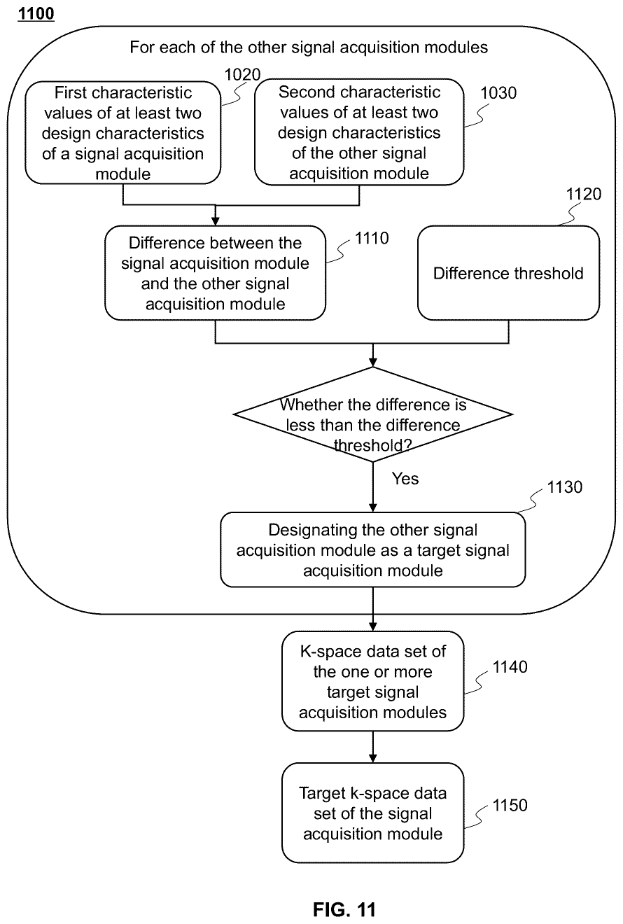

In some embodiments, the processor may determine one or more target signal acquisition modules from one or more other signal acquisition modules based on first characteristic values of at least two design characteristics of the signal acquisition module and second characteristic values of at least two design characteristics of each of the one or more other signal acquisition modules; determine the target k-space data set based on k-space data sets of the one or more target signal acquisition modules. More descriptions regarding the foregoing embodiments may be found in FIG. 11 and the related descriptions thereof.

In 322, the MR image of the target object corresponding to the signal acquisition module is reconstructed based on the target k-space data set. In some embodiments, operation 322 may be performed by the reconstruction module 230.

In some embodiments, the processor may obtain the MR image corresponding to the signal acquisition module by reconstructing the target k-space data set using a reconstruction algorithm. Exemplary reconstruction algorithms include fast Fourier transform (FFT), compression sensing reconstruction algorithms, fitted regression algorithms, etc.

In some embodiments, for each signal acquisition module, the processor may obtain the MR image corresponding to the signal acquisition module by performing operation 321 and operation 322 on the k-space data set corresponding to the signal acquisition module.

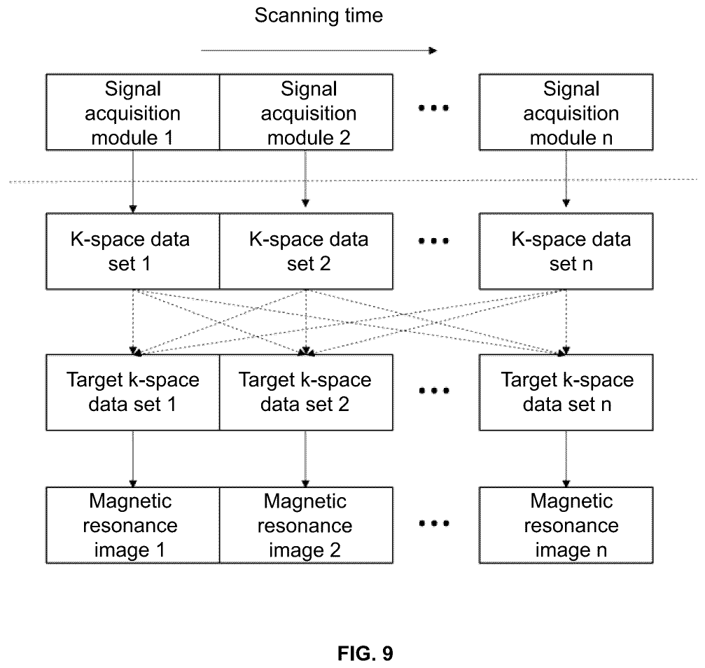

Merely by way of example, as shown in FIG. 9, in the MR scan of the target object, the imaging sequence includes n signal acquisition modules. A signal acquisition module 1 obtains a k-space data set 1, a signal acquisition module 2 obtains a k-space data set 2, . . . , and a signal acquisition module n obtains a k-space data set n. The processor determines, by separately executing operation 321 on the k-space data sets obtained by the n signal acquisition modules, a target k-space data set corresponding to each signal acquisition module among the n signal acquisition modules. As shown in FIG. 9, a target k-space data set 1 corresponding to signal acquisition module 1, the target k-space data set 2 corresponding to the signal acquisition module 2, . . . , and the target k-space data set n corresponding to the signal acquisition module n are determined. The processor then obtains an MR image 1 by reconstructing the target k-space data set 1, obtains an MR image 2 by reconstructing the target k-space data set 2, . . . , and obtains an MR image n by reconstructing the target k-space data set n.

In some embodiments of the present disclosure, signal acquisition modules with different design characteristics are obtained by modularizing signal acquisition manners of different functions and applying these signal acquisition modules in one scan, which allows obtaining images with different contrasts in one scan, improving scanning efficiency. With different signal acquisition modules having at least two different design characteristics, more diversified MR data may be collected, further improving the contrasts of different images.

In some embodiments, the processor may generate a quantitative parameter map based on the MR images corresponding to the at least two signal acquisition modules.

The quantitative parameter map includes quantitative analysis results relating to parameters of the target object and/or the MR device. For example, the quantitative parameter map may include a quantitative map of relaxation parameters (e.g., a quantitative map of T1, a quantitative map of T2*), a quantitative map of proton density, a quantitative map of magnetization, a map of radio frequency field distribution, a map of sensitivity distribution of receiving coils, etc.

In some embodiments, the processor may generate the quantitative parameter map by processing the MR images corresponding to the at least two signal acquisition modules through a quantitative analysis model. The quantitative analysis model is a machine learning model, such as a deep neural network (DNN) model. The processor may also generate the quantitative parameter map by any existing MR image analysis algorithms.

In some embodiments of the present disclosure, MR images corresponding to a plurality of signal acquisition modules are used to generate one or more quantitative parameter maps, which may integrate and analyze images with different contrast information, and provide more data support for clinical diagnosis.

### {{FIG. 4}}

FIG. 4 is a flowchart illustrating an exemplary process for determining a target k-space data set corresponding to a signal acquisition module according to some embodiments of the present disclosure. In some embodiments, process 400 may be used to achieve operation 321.

In 410, a k-space outer region corresponding to the signal acquisition module and outer k-space data in the k-space outer region collected by the signal acquisition module are determined based on a k-space data set corresponding to the signal acquisition module.

The k-space outer region refers to a peripheral region in the k-space.

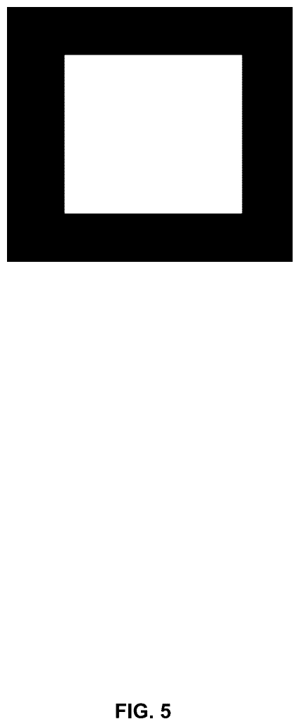

The outer k-space data refers to k-space data in the k-space outer region. For example, as shown in FIG. 5, the box represents the k-space; the black part in the box represents the k-space outer region, the k-space data in the black part is the outer k-space data; the white part in the box represents a k-space middle region, the k-space data in the white part is center k-space data.

In some embodiments, the processor may determine the k-space outer region based on a preset percentage. The preset percentage refers to a ratio of an amount of outer k-space data in the k-space outer region to an amount of the entire k-space data set. For example, the preset percentage may include 10%, 25%, 40%, 50%, etc. The larger the preset percentage, the larger the proportion of the outer k-space data in the k-space data set.

In some embodiments, the k-space outer region of the signal acquisition module is determined based on the size of k-space and a quality of the k-space data contained in the k-space data set corresponding to the signal acquisition module.

The quality of the k-space data can reflect an integrity of the k-space data. For example, the quality of the k-space data may be determined based on an undersampling rate. The higher the undersampling rate, the worse the quality of the k-space data. As another example, the quality may be determined based on a density of the k-space data, a signal-to-noise ratio, etc. The greater the density of the k-space data and the higher the signal-to-noise ratio, the better the quality of the k-space data.

In some embodiments, the size of the k-space outer region is related to the size of k-space. For example, the larger the k-space is, the larger the corresponding k-space edge area is. In some embodiments, the size of the k-space outer region may be a fixed value (such as a preset value), that is, for k-spaces of different sizes, the corresponding k-space outer regions have the same size. In some embodiments, the better the quality of the k-space data contained in the k-space data set, the smaller the k-space outer region.

In some embodiments, the processor may determine a size of the k-space outer region in other ways. For example, the processor may determine the size of the k-space outer region based on a scanning speed of the signal acquisition module on the target object during the MR scan. In some embodiments, the higher the scanning speed of the signal acquisition module on the target object, the larger the k-space outer region.

In some embodiments of the present disclosure, by determining the size of the k-space outer region based on the size of k-space and quality of the k-space data, the completeness and abundance of the data can be taken into consideration, which is conducive to improving the quality of the subsequently obtained target k-space data.

In 420, reference k-space data is determined.

The reference k-space data refers to k-space data corresponding to the k-space outer region that can be used as a reference for updating the outer k-space data of the signal acquisition module. In some embodiments, the reference k-space data includes k-space data of the k-space outer region collected by the one or more other signal acquisition modules.

In some embodiments, for each of the other signal acquisition module(s), the processor may designate the k-space outer region of the signal acquisition module as a k-space outer region of the other signal acquisition module, and designate k-space data in the k-space outer region collected by the other signal acquisition module as the reference k-space data. In some embodiments, the processor may only designate a part of the k-space data in the k-space outer region collected by the other signal acquisition module as the reference k-space data.

In 430, the outer k-space data is updated based on the reference k-space data.

In some embodiments, if the reference k-space data includes data at a sampling position in the k-space and the outer k-space data does not include data at that sampling position, the processor may fill the data at that sampling position in the reference k-space data into the outer k-space data to obtain the updated outer k-space data.

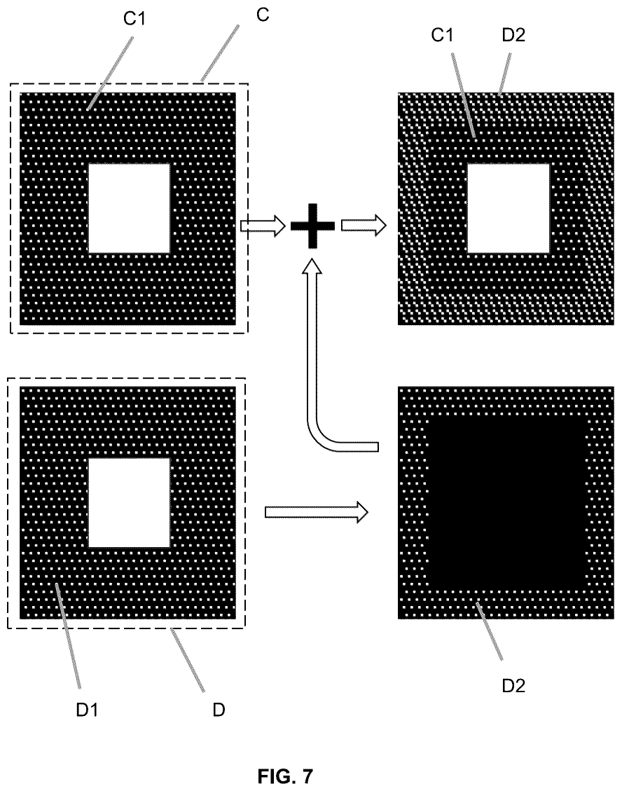

Merely by way of example, as shown in FIG. 7, C is the k-space data set collected by the signal acquisition module, region C1 is the k-space outer region of the signal acquisition module, and data in the region C1 is the outer k-space data collected by the signal acquisition module; D is the k-space data set collected by the other signal acquisition module, and data in region D1 is the outer k-space data collected by the other signal acquisition module, i.e., the reference k-space data. For the other signal acquisition module, the reference k-space data in region D2 (which is part of the region D1) has different sampling positions from the outer k-space data of the signal acquisition module. In such cases, the reference k-space data in the region D2 is filled into the k-space outer region C1 of the signal acquisition module, the reference k-space data in the region D2 and the original outer k-space data in the region C1 form the updated outer k-space data.

In some embodiments, if both the outer k-space data and the reference k-space data include data at the same sampling position in the k-space, the processor may determine an average of such data in both the outer k-space data and the reference k-space data, and designate the determined average value as the updated outer k-space data corresponding to that sampling position.

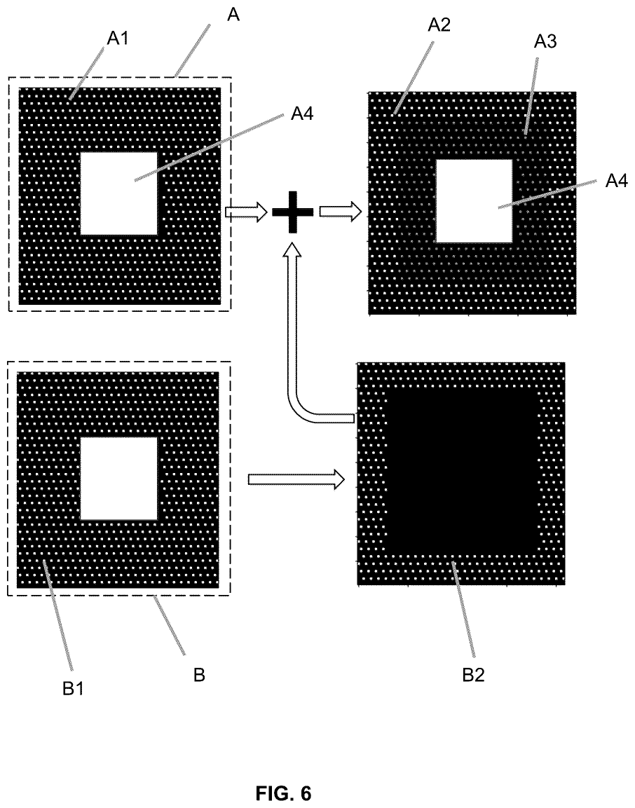

Merely by way of example, as shown in FIG. 6, A is the k-space data set collected by the signal acquisition module, region A1 is the k-space outer region of the signal acquisition module, and data in the region A1 is the outer k-space data collected by the signal acquisition module; B is the k-space data set collected by the other signal acquisition module, and data in region B1 is the outer k-space data collected by the other signal acquisition module, i.e., the reference k-space data. For the other signal acquisition module, the reference k-space data in region B2 (which is part of the region B1) has the same sampling positions as the outer k-space data of the signal acquisition module. In such cases, the reference k-space data in the region B2 and the outer k-space data collected by the signal acquisition module in region A2 corresponding to the region B2 are averaged, and the averaged data may be part of the updated outer k-space data. Referring to FIG. 6, the updated outer k-space data includes the average data in the region A2 and original outer k-space data collected by the signal acquisition module in region A3, wherein the region A2 and the region A3 form the k-space outer region of the signal acquisition module.

In some embodiments, for each of the one or more other signal acquisition modules, the processor may determine a weight of the other signal acquisition module based on first characteristic values of the at least two design characteristics of the signal acquisition module and second characteristic values of the at least two design characteristics of the other signal acquisition module. The outer k-space data is updated based on the reference k-space data and the weight of each of the other signal acquisition module(s).

The weight may reflect a magnitude of a reference value of the reference k-space data collected by the other signal acquisition module to the outer k-space data collected by the signal acquisition module.

In some embodiments, the weight is determined based on the similarity degree between the first characteristic values of the signal acquisition module and the second characteristic values of the other signal acquisition module. The higher the similarity degree, the greater the weight. It should be understood that the contrasts of the MR images collected by two signal acquisition modules may have a higher similarity degree if the two signal acquisition modules have more similar design characteristics, and the k-space data collected by these two signal acquisition modules have higher reference values with respect to each other.

In some embodiments, if both the outer k-space data and the reference k-space data include data at the same sampling position in the k-space, the processor may perform weighted summation on such data in the outer k-space data and the reference k-space data based on their weights to obtain a value, which is determined as the updated outer k-space data corresponding to that sampling position.

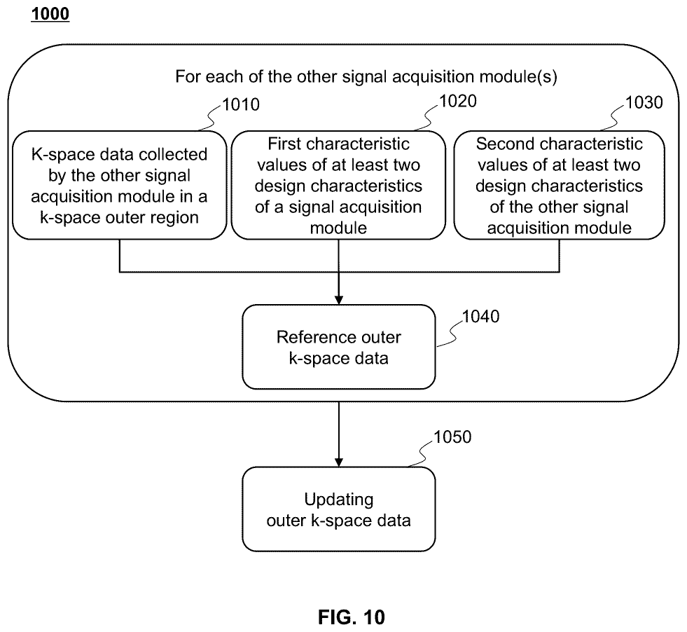

In some embodiments, for each of the other signal acquisition module(s), the processor may determine reference outer k-space data based on the k-space data in the k-space outer region collected by the other signal acquisition module, the first characteristic values of the at least two design characteristics of the signal acquisition module, and the second characteristic values of the at least two design characteristics of the other signal acquisition module; update the outer k-space data based on the reference outer k-space data corresponding to the other signal acquisition module. More descriptions regarding the foregoing embodiments may be found in FIG. 10 and the related descriptions thereof.

In some embodiments of the present disclosure, each of the other signal acquisition module(s) is assigned with a weight based on the similarity degree between the first characteristic values of the signal acquisition module and second characteristic values of the other signal acquisition module. In this way, the outer k-space data is updated based on more reference k-space data with higher reference value, thereby improving the accuracy of the updated outer k-space data and improving the quality of the reconstructed MR image.

In 440, the target k-space data set is determined based on the updated outer k-space data of the signal acquisition module and the original k-space data in other regions in k-space collected by the signal acquisition module.

In some embodiments, the processor may merge the updated outer k-space data with the original k-space data in other regions in k-space collected by the signal acquisition module (e.g., a center region of k-space), determine the merged k-space data as the target k-space data set corresponding to the signal acquisition module. Merely by way of example, as shown in FIG. 6, region A4 is the center region corresponding to the signal acquisition module, data in the region A2 and the region A3 is the updated outer k-space data, then the data in the region A2, the region A3, and the region A4 form the target k-space data set corresponding to the signal acquisition module.

In some embodiments of the present disclosure, k-space data in the k-space outer region collected by different signal acquisition modules are shared with each other to improve the quality of the data in the k-space outer region, and thus improve the quality of the reconstructed MR image. In addition, by using such a data sharing mechanism, the MR scan can be performed with a higher undersampling rate in the k-space outer region, which may improve the scanning speed without affecting the reconstruction quality.

It should be noted that the foregoing descriptions of the process 300 and the process 400 are for the purpose of exemplification and illustration only and do not limit the scope of application of the present disclosure. For a person skilled in the art, various corrections and changes may be made to the process 300 and the process 400 under the guidance of the present disclosure. However, these corrections and changes remain within the scope of the present disclosure.

### {{FIG. 10}}

FIG. 10 is a schematic diagram illustrating an exemplary process 1000 for updating outer k-space data according to some embodiments of the present disclosure. In some embodiments, operation 430 in FIG. 4 may be achieved by performing process 1000 in FIG. 10.

As illustrated in FIG. 10, for each of the other signal acquisition module(s), the processor may determine reference outer k-space data 1040 based on k-space data 1010 collected by the other signal acquisition module in a k-space outer region, first characteristic values 1020 of at least two design characteristics of the signal acquisition module (referred to as the first characteristic values of the signal acquisition module hereinafter), and second characteristic values 1030 of the at least two design characteristics of the other signal acquisition module (referred to as the second characteristic values of the other signal acquisition module hereinafter); update outer k-space data 1050 collected by the signal acquisition module based on the reference outer k-space data 1040 corresponding to each of the other signal acquisition module(s).

The first characteristic values 1020 refer to characteristic values of at least two design characteristics of a signal acquisition module being analyzed currently. The second characteristic values 1030 refer to characteristic values of the at least two design characteristics of the other signal acquisition module. Updating the outer k-space data 1050 collected by the signal acquisition module directly based on the k-space edge data 1010 collected by the other signal acquisition modules may have low accuracy due to the difference between the first characteristic values 1020 of the signal acquisition module and the second characteristic values 1030 of the other signal acquisition modules. Therefore, the k-space data in the k-space outer region corresponding to the signal acquisition module with the first characteristic values 1020 may be predicted based on the k-space data 1010, the first characteristic values 1020, and the second characteristic values 1030, which is used as a reference. The reference outer k-space data 1040 refers to data in the k-space outer region obtained by prediction considering the difference between the first and second characteristic values, which is more compatible with the signal acquisition module being analyzed currently.

In some embodiments, the processor may adjust the k-space data 1010 based on the difference between the first characteristic values 1020 and the second characteristic values 1030 to determine the reference outer k-space data 1040. In some embodiments, the adjustment of the k-space data 1010 may be performed based on prior knowledge about the relationships between k-space data and the design characteristics or by a user based on experience.

In some embodiments, the processor may determine the reference outer k-space data 1040 through a k-space data prediction model. The k-space data prediction model is a machine learning model, such as a deep neural network (DNN) model. In some embodiments, an input of the k-space data prediction model includes the k-space data 1010, the first characteristic values 1020, and the second characteristic values 1030. An output of the k-space data prediction model includes the reference outer k-space data 1040.

In some embodiments, the k-space data prediction model may be obtained by training an initial k-space data prediction model using first training samples. Each first training sample includes a first training input and a first training label. The first training input includes first sample k-space data of a sample object collected by a first sample signal acquisition module, first design characteristic values of the first sample signal acquisition module, and second design characteristic values of a second sample signal acquisition module. The first training label includes second sample k-space data of the sample object collected by the second sample signal acquisition module with the second design characteristic values. Specifically, the first sample k-space data and the second sample k-space data are obtained by performing data collection, respectively, on one sample object utilizing the first sample signal acquisition module and the second sample signal acquisition module with at least two different design characteristics. The first sample k-space data and the second sample k-space data are similar to the k-space data 1010, and both of them are k-space data in the k-space outer region. The first design characteristic values and the first sample k-space data corresponding to the first sample signal acquisition module, as well as the second design characteristic values corresponding to the second sample signal acquisition module, may be designated as the first training input. The second sample k-space data corresponding to the second sample signal acquisition module may be designated as the first training label.

In some embodiments, the k-space data prediction model is a generator in a generative adversarial network (GAN) model. The k-space data prediction model may be generated by training an initial GAN model. The initial GAN model includes an initial generator and an initial discriminator. The initial generator includes an initial characteristic extraction module and an initial data prediction module. Sample feature information may be obtained by inputting the first training input into the initial feature extraction module. The initial data prediction module processes sample feature information to obtain predicted k-space data. The initial discriminator is configured to discriminate authenticity of the predicted k-space data and the first training label. The initial GAN model is updated through iterations based on a difference between the predicted k-space data and the first training label, and the discrimination results. During the training process, model parameters are constantly adjusted to make the predicted k-space data generated by the initial generator as close as possible to the first training label to confuse the initial discriminator, and to make the initial discriminator have better discrimination capability. The initial generator after training is designated as the k-space data prediction model.

In some embodiments of the present disclosure, machine learning techniques are used to learn the generation mechanism of the reference outer k-space data, making the determination of reference outer k-space data more accurate. Meanwhile, the k-space data prediction model may be used to improve the efficiency of generating the reference outer k-space data.

The processor then updates the outer k-space data based on the reference outer k-space data corresponding to the other signal acquisition module(s), which is performed in a similar manner to updating the outer k-space data based on the reference k-space data in step 430.

In some embodiments of the present disclosure, the reference outer k-space data is determined based on the first characteristic values of the signal acquisition module and the second characteristic values of the other signal acquisition module, which takes into account the difference between the characteristic values corresponding to the signal acquisition module and the other signal acquisition module. Thus, the predicted reference outer k-space data is made to be more consistent with the data collected using the signal acquisition module with the first characteristic values, thereby improving the accuracy of updating the data.

### {{FIG. 11}}

FIG. 11 is a schematic diagram illustrating an exemplary process for determining a target k-space data set corresponding to a signal acquisition module according to some embodiments of the present disclosure. In some embodiments, operation 322 in FIG. 3 may be achieved by the process 1100.

As shown in FIG. 11, the processor may determine one or more target signal acquisition modules from multiple other signal acquisition modules based on the first characteristic values 1020 of at least two design characteristics of a signal acquisition module and the second characteristic values 1030 of at least two design characteristics of each of the other signal acquisition module(s); determine a target k-space data set 1150 corresponding to the signal acquisition module based on the k-space data set 1140 of one or more target signal acquisition modules.

In some cases, when a difference between the second characteristic values 1030 of the other signal acquisition module and the first characteristic values 1020 of the signal acquisition module is too large, the k-space data set collected by that other signal acquisition module has a low reference value for the signal acquisition module. In such cases, in some embodiments of the present disclosure, one or more target signal acquisition modules, which have a higher reference value for the signal acquisition module, are selected from multiple other signal acquisition modules for subsequent calculations.

In some embodiments, as shown in FIG. 11, for each of the other signal acquisition modules, the processor may determine a difference 1110 between the signal acquisition module and the other signal acquisition module based on the first characteristic values 1020 of the signal acquisition module and the second characteristic values 1030 of the other signal acquisition module; obtain a difference threshold 1120; in response to determining that the difference is less than the difference threshold, the processor may designate the other signal acquisition module as a target signal acquisition module 1130.

The difference between the signal acquisition module and the other signal acquisition module may indicate a difference between the sets of k-space data or images collected by the signal acquisition module and the other signal acquisition module. For example, the difference may indicate a difference between the image contrasts of the images collected by the signal acquisition module and the other signal acquisition module.

In some embodiments, the processor may predict a first image contrast corresponding to the signal acquisition module based on the first characteristic values of the signal acquisition module; predict a second image contrast corresponding to the other signal acquisition module based on the second characteristic values of the other signal acquisition modules; determine the difference 1110 between the signal acquisition module and the other signal acquisition module based on the first image contrast and the second image contrast. For example, the processor may predict the first image contrast corresponding to the signal acquisition module based on the first characteristic values and a relationship between the design characteristics and the image contrast. Similarly, the processor may predict the second image contrast corresponding to the other signal acquisition module based on the second characteristic values and the relationship between the design characteristics and the image contrast.

In some embodiments, the processor may determine the first image contrast corresponding to the signal acquisition module and/or the second image contrast corresponding to the other signal acquisition module using a trained contrast prediction model. The contrast prediction model is a machine learning model, such as a convolutional neural network (CNN) model. The following descriptions take the determination of the first image contrast as an example, the second image contrast can be determined in a similar manner.

An input of the contrast prediction model includes the first characteristic values of the signal acquisition module. An output of the contrast prediction model includes the first image contrast corresponding to the signal acquisition module. In some embodiments, the input of the contrast prediction model further includes characteristic values of other design characteristics of the signal acquisition module. The characteristic values of other design features are the same as those of the other signal acquisition module. Merely by way of example, refer to FIG. 8, the signal acquisition module b and the signal acquisition module c contain different counts of TEs and TRs, but have the same count of flip angles. When determining an image contrast corresponding to the signal acquisition module b, in addition to inputting the counts and/or values of the TEs and TRs, the count of flip angles and a degree of flip angles may also be input into the contrast prediction model, so that the contrast prediction model may obtain more accurate prediction results based on more design characteristics when determining the contrast.

In some embodiments, the contrast prediction model may be trained through a plurality of second training samples. Each second training sample includes a second training input and a second training label. The second training input includes sample characteristic values of a sample signal acquisition module, and the second training label includes a sample image contrast corresponding to a sample image collected by the sample signal acquisition module with the sample characteristic values. Specifically, the sample signal acquisition module may be applied to a sample object to reconstruct the sample image based on the collected data, and a contrast of the sample image may be designated as the sample image contrast.

Merely by way of example, the second training inputs are input into an initial contrast prediction model. A value of a loss function is determined based on the second training label and an output of the initial contrast prediction model, and parameters of the initial contrast prediction model are updated through iterations based on the value of the loss function. When a preset condition is met, the model training is completed, and the trained contrast prediction model is obtained. The preset conditions may be that the loss function converges, a count of the iteration reaches a threshold, etc.

In some embodiments, machine learning techniques are used to learn the prediction of image contrasts corresponding to different characteristic values, making the obtained image contrasts more accurate while improving the efficiency of prediction.

After determining the first image contrast and the second image contrast, the processor may calculate a difference between the first image contrast and the second image contrast, and designate the calculated difference as the difference between the signal acquisition module and the other signal acquisition module.

Furthermore, the processor may compare the difference between the signal acquisition module and the other signal acquisition module with the difference threshold. In some embodiments, the difference threshold may be a default value, a preset value, a user input value, etc. In some embodiments, the difference threshold may be determined based on a region of interest of the target object and/or a quantitative parameter map to be generated. For example, a storage device may previously store a corresponding relationship between difference thresholds and different regions of interest. The processor may access the storage device and determine the difference threshold based on the corresponding relationship. It should be understood that different regions of interest have different contrasts in a reconstructed image (such as the quantitative parameter map) due to different compositions included in the different regions of interest. Moreover, there are inherent differences between different quantitative parameter maps. Therefore, the difference threshold may be determined based on the region of interest and/or the quantitative parameter map to be generated, making the selection of the target signal acquisition module more accurate.

In some embodiments, the processor may designate all other signal acquisition modules with differences less than the difference threshold as the target signal acquisition module(s). In some embodiments, the processor may sort the other signal acquisition modules with differences less than the difference threshold in ascending order and designate the top n other signal acquisition modules as the target signal acquisition module(s), where n is a default value, a preset value, etc.

The processor then determines the target k-space data set corresponding to the signal acquisition module based on the k-space data set of one or more target signal acquisition modules, which is performed in a similar manner to determining the target k-space data set corresponding to the signal acquisition module based on the k-space data sets of the signal acquisition module and one or more other signal acquisition modules in operation 321, and may not be repeated here.

In some embodiments of the present disclosure, the difference between image contrasts corresponding to different signal acquisition modules is considered, and a signal acquisition module with a smaller difference in image contrasts compared to the signal acquisition module to be analyzed is selected as a target signal acquisition module. The selected target signal acquisition module corresponds to a k-space data set that has a higher reference value. Therefore, the accuracy of the ultimately determined target k-space data set is higher.

The present disclosure also provides a device for MR imaging. The device includes at least one processor and at least one storage device. The at least one storage device is configured to store computer instructions. The at least one processor is configured to execute at least some of the computer instructions to implement the method for MR imaging described in any of the above embodiments.

The present disclosure also provides a non-transitory computer-readable storage medium storing computer instructions. When the computer reads the computer instructions in the storage medium, the computer implements the method for MR imaging.

It should be noted that the processes 300, 400, 1000, and 1100 and the descriptions thereof are provided for the purposes of illustration, and not intended to limit the scope of the present disclosure. For persons having ordinary skills in the art, various modifications and changes in the forms and details of the application of the above method and system may occur without departing from the principles of the present disclosure. However, those variations and modifications also fall within the scope of the present disclosure. For example, the operations of the illustrated processes are intended to be illustrative. In some embodiments, the processes may be accomplished with one or more additional operations not described, and/or without one or more of the operations discussed. Additionally, the order in which the operations of the processes and regarding descriptions are not intended to be limiting.

Having thus described the basic concepts, it may be rather apparent to those skilled in the art after reading this detailed disclosure that the foregoing detailed disclosure is intended to be presented by way of example only and is not limiting. Various alterations, improvements, and modifications may occur and are intended to those skilled in the art, though not expressly stated herein. These alterations, improvements, and modifications are intended to be suggested by this disclosure, and are within the spirit and scope of the exemplary embodiments of this disclosure.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of this specification are not necessarily all referring to the same embodiment. Furthermore, the particular features, structures or characteristics may be combined as suitable in one or more embodiments of the present disclosure.

Further, it will be appreciated by one skilled in the art, aspects of the present disclosure may be illustrated and described herein in any of a number of patentable classes or context including any new and useful process, machine, manufacture, or composition of matter, or any new and useful improvement thereof. Accordingly, aspects of the present disclosure may be implemented entirely hardware, entirely software (including firmware, resident software, micro-code, etc.) or combining software and hardware implementation that may all generally be referred to herein as a “module,” “unit,” “component,” “device,” or “system.” Furthermore, aspects of the present disclosure may take the form of a computer program product embodied in one or more computer readable media having computer readable program code embodied thereon.

A computer readable signal medium may include a propagated data signal with computer readable program code embodied therein, for example, in baseband or as part of a carrier wave. Such a propagated signal may take any of a variety of forms, including electro-magnetic, optical, or the like, or any suitable combination thereof. A computer readable signal medium may be any computer readable medium that is not a computer readable storage medium and that may communicate, propagate, or transport a program for use by or in connection with an instruction execution system, apparatus, or device. Program code embodied on a computer readable signal medium may be transmitted using any appropriate medium, including wireless, wireline, optical fiber cable, RF, or the like, or any suitable combination of the foregoing.

Computer program code for carrying out operations for aspects of the present disclosure may be written in any combination of one or more programming languages, including an subject oriented programming language such as Java, Scala, Smalltalk, Eiffel, JADE, Emerald, C++, C#, VB. NET, Python or the like, conventional procedural programming languages, such as the “C” programming language, Visual Basic, Fortran 2003, Perl, COBOL 2002, PHP, ABAP, dynamic programming languages such as Python, Ruby and Groovy, or other programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider) or in a cloud computing environment or offered as a service such as a Software as a Service (SaaS).

Furthermore, the recited order of processing elements or sequences, or the use of numbers, letters, or other designations therefore, is not intended to limit the claimed processes and methods to any order except as may be specified in the claims. Although the above disclosure discusses through various examples what is currently considered to be a variety of useful embodiments of the disclosure, it is to be understood that such detail is solely for that purpose, and that the appended claims are not limited to the disclosed embodiments, but, on the contrary, are intended to cover modifications and equivalent arrangements that are within the spirit and scope of the disclosed embodiments. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. This method of disclosure, however, is not to be interpreted as reflecting an intention that the claimed subject matter requires more features than are expressly recited in each claim. Rather, claim subject matter lie in less than all features of a single foregoing disclosed embodiment.

In some embodiments, the numbers expressing quantities or properties used to describe and claim certain embodiments of the application are to be understood as being modified in some instances by the term “about,” “approximate,” or “substantially.” For example, “about,” “approximate,” or “substantially” may indicate a certain variation (e.g., ±1%, ±5%, ±10%, or ±20%) of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the application are approximations, the numerical values set forth in the specific examples are reported as precisely as practicable. In some embodiments, a classification condition used in classification or determination is provided for illustration purposes and modified according to different situations. For example, a classification condition that “a value is greater than the threshold value” may further include or exclude a condition that “the probability value is equal to the threshold value.”

What is claimed is:

1. A method for magnetic resonance (MR) imaging, implemented on a computing device having at least one processor and at least one storage device, the method comprising:
obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules; and
for each signal acquisition module of the at least two signal acquisition modules,
determining a target k-space data set based on the k-space data set corresponding to the signal acquisition module and the one or more k-space data sets corresponding to one or more other signal acquisition modules among the at least two signal acquisition modules; and
reconstructing an MR image of the target object corresponding to the signal acquisition module based on the target k-space data set.

2. The MRI method of claim 1, wherein the at least two design characteristics include a first design characteristic, and the first design characteristic relates to the type and the count of elements included in each signal acquisition module.

3. The MRI method of claim 2, wherein the elements include at least one of a pulse, a flip angle, a readout gradient polarity, an echo signal acquisition, or a magnetization preparation strategy.

4. The MRI method of claim 1, wherein the at least two design characteristics include a second design characteristic, and the second design characteristic relates to a scanning parameter corresponding to each signal acquisition module.

5. The MRI method of claim 1, wherein the determining a target k-space data set includes:
determining a k-space outer region corresponding to the signal acquisition module and outer k-space data in the k-space outer region collected by the signal acquisition module based on the k-space data set corresponding to the signal acquisition module;
determining reference k-space data, wherein the reference k-space data includes k-space data in the k-space outer region collected by the one or more other signal acquisition modules;
updating the outer k-space data based on the reference k-space data; and
determining the target k-space data set based on the updated outer k-space data and original k-space data in other regions in k-space collected by the signal acquisition module.

6. The MRI method of claim 5, wherein the k-space outer region corresponding to the signal acquisition module is determined based on the size of k-space and the quality of k-space data in the k-space data set corresponding to the signal acquisition module.

7. The MRI method of claim 5, wherein the one or more other signal acquisition modules include multiple other signal acquisition modules, and the updating the outer k-space data based on the reference k-space data includes:
for each of the other signal acquisition modules, determining a weight of the other signal acquisition module based on first characteristic values of the at least two design characteristics of the signal acquisition module and second characteristic values of the at least two design characteristics of the other signal acquisition module; and
updating the outer k-space data based on the reference k-space data and the weight of each of the other signal acquisition modules.

8. The MRI method of claim 5, wherein the updating the outer k-space data based on the reference k-space data includes:
for each of the one or more other signal acquisition modules, determining reference outer k-space data based on k-space data in the k-space outer region collected by the other signal acquisition module, first characteristic values of the at least two design characteristics of the signal acquisition module, and second characteristic values of the at least two design characteristics of the other signal acquisition module; and
updating the outer k-space data based on the reference outer k-space data corresponding to the one or more other signal acquisition modules.

9. The MRI method of claim 1, further comprising:
generating a quantitative parameter map based on the MR images corresponding to the at least two signal acquisition modules.

10. The MRI method of claim 1, wherein the one or more other signal acquisition modules include multiple other signal acquisition modules, the determining a target k-space data set of includes:
determining, based on first characteristic values of the at least two design characteristics of the signal acquisition module and second characteristic values of the at least two design characteristics of each of the other signal acquisition modules, one or more target signal acquisition modules from the other signal acquisition modules; and
determining the target k-space data set based on the k-space data sets of the one or more target signal acquisition modules.

11. The method of claim 10, the determining one or more target signal acquisition modules from the other signal acquisition modules includes:
for each of the other signal acquisition modules,
determining a difference between the signal acquisition module and the other signal acquisition module based on the first characteristic values of the signal acquisition module and the second characteristic values of the other signal acquisition module;
obtaining a difference threshold; and
in response to determining that the difference is less than the difference threshold, designating the other signal acquisition module as one of the one or more target signal acquisition modules.

12. The method of claim 1, wherein the at least two signal acquisition modules are configured to under-sample different locations in k-space utilizing a same undersampling pattern.

13. A system, comprising:
at least one storage device storing a set of instructions for magnetic resonance imaging (MRI); and
at least one processor configured to communicate with the at least one storage device, wherein when executing the set of instructions, the at least one processor is configured to direct the system to perform operations including:
obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules; and
for each signal acquisition module of the at least two signal acquisition modules,
determining a target k-space data set based on the k-space data set corresponding to the signal acquisition module and the one or more k-space data sets corresponding to one or more other signal acquisition modules among the at least two signal acquisition modules; and
reconstructing an MR image of the target object corresponding to the signal acquisition module based on the target k-space data set.

14. The system of claim 13, wherein the at least two design characteristics include a first design characteristic, and the first design characteristic relates to the type and the count of elements included in each signal acquisition module.

15. The system of claim 13, wherein the at least two design characteristics include a second design characteristic, and the second design characteristic relates to a scanning parameter corresponding to each signal acquisition module.

16. The system of claim 13, wherein the determining a target k-space data set includes:
determining a k-space outer region corresponding to the signal acquisition module and outer k-space data in the k-space outer region collected by the signal acquisition module based on the k-space data set corresponding to the signal acquisition module;
determining reference k-space data, wherein the reference k-space data includes k-space data in the k-space outer region collected by the one or more other signal acquisition modules;
updating the outer k-space data based on the reference k-space data; and
determining the target k-space data set based on the updated outer k-space data and original k-space data in other regions in k-space collected by the signal acquisition module.

17. The system of claim 16, wherein the one or more other signal acquisition modules include multiple other signal acquisition modules, and the updating the outer k-space data based on the reference k-space data includes:
for each of the other signal acquisition modules, determining a weight of the other signal acquisition module based on first characteristic values of the at least two design characteristics of the signal acquisition module and second characteristic values of the at least two design characteristics of the other signal acquisition module; and
updating the outer k-space data based on the reference k-space data and the weight of each of the other signal acquisition modules.

18. The system of claim 16, wherein the updating the outer k-space data based on the reference k-space data includes:
for each of the one or more other signal acquisition modules, determining reference outer k-space data based on k-space data in the k-space outer region collected by the other signal acquisition module, first characteristic values of the at least two design characteristics of the signal acquisition module, and second characteristic values of the at least two design characteristics of the other signal acquisition module; and
updating the outer k-space data based on the reference outer k-space data corresponding to the one or more other signal acquisition modules.

19. The system of claim 13, wherein the operations further include:
generating a quantitative parameter map based on the MR images corresponding to the at least two signal acquisition modules.

20. A non-transitory computer readable medium, comprising a set of instructions, wherein when executed by at least one processor, the set of instructions direct the at least one processor to effectuate a method, the method comprising:
obtaining k-space data collected during an MR scan of a target object, wherein the MR scan is performed by applying an imaging sequence to the target object, the imaging sequence includes at least two signal acquisition modules of a same sequence type, different signal acquisition modules of the at least two signal acquisition modules have at least two design characteristics with different characteristic values, and the k-space data includes at least two k-space data sets each of which corresponds to one of the at least two signal acquisition modules; and
for each signal acquisition module of the at least two signal acquisition modules,
determining a target k-space data set based on the k-space data set corresponding to the signal acquisition module and the one or more k-space data sets corresponding to one or more other signal acquisition modules among the at least two signal acquisition modules; and
reconstructing an MR image of the target object corresponding to the signal acquisition module based on the target k-space data set.
